(19) United States
(12) Patent Application Publication
(10) Pub. No.: US 2024/0120706 A1
(43) Pub. Date: Apr. 11, 2024

(54) CONTINUOUS-WAVE LASER SOURCE AND MAKING A CONTINUOUS-WAVE LASER SOURCE

(71) Applicant: Government of the United States of America, as represented by the Secretary of Commerce, Gaithersburg, MD (US)

(72) Inventors: Scott Brian Papp, Boulder, CO (US); Jennifer Anne Black, Boulder, CO (US)

(21) Appl. No.: 18/483,926

(22) Filed: Oct. 10, 2023

Related U.S. Application Data
(60) Provisional application No. 63/414,002, filed on Oct. 7, 2022.

(51) Int. Cl. H01S 5/026; H01S 5/11

(52) U.S. Cl. CPC H01S 5/026; H01S 5/11

(57) ABSTRACT

A method of designing a continuous-wave laser source having a target output wavelength and an input laser with a wavelength different from the target output wavelength includes the steps of receiving the target output wavelength, and subordinate properties of the laser source; determining a candidate wavelength of the input laser and materials of the substrate, lower cladding, photonic device layer (PDL), and upper cladding; producing an optimal design of a photonic crystal resonator (PhCR) enabling optical parametric oscillation (OPO); and producing an optimal design of the input and output PhCR waveguide couplers. The OPO is phase-matched.

### CROSS REFERENCE TO RELATED APPLICATIONS

This application claims the benefit of U.S. Provisional Patent Application Ser. No. 63/414,002 (filed Oct. 7, 2022), which is herein incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### SUMMARY OF THE INVENTION

Advances in laser applications especially in fluctuating environments and with less developed spectral ranges drives innovation in laser and integrated photonics technologies. For example, quantum-based sensors, quantum-information systems, atomic and molecular spectroscopy, data communication, and photonic-signal generation require diverse laser wavelength access to enhance performance and enable novel application opportunities. Hence, the development of widely deployable laser sources that support wavelength customization would be broadly utilized. Laser technologies based on solid-state materials, doped optical fibers, and semiconductor gain with bulk cavities are commercially mature with well-understood cost and performance tradeoffs. Monolithically integrated semiconductor lasers satisfy a substantial range of applications; however, no semiconductor material offers sufficiently low optical loss to support narrow spectral linewidth commensurate with bulk and fiber lasers. Heterogeneously integrated lasers with fabrication on a common substrate have been developed in widely used spectral ranges, and leveraging low loss waveguide materials has enabled narrow linewidth and ultraprecise laser stabilization. However, heterogeneous laser fabrication is exceptionally complex limiting wavelength access. Therefore, exemplary embodiments of nonlinear wavelength conversion of a pump source by use of integrated photonics is a flexible tool to expand the palette of any laser platform.

Optical-parametric oscillation (OPO) in Kerr ring resonators is usable to transform the flat state of a continuous-wave pump laser to the Turing pattern composed of a few wavelengths. In this case, phase matching for OPO is intrinsic, owing to the balance between Kerr frequency shifts and anomalous group-velocity dispersion (GVD). Moreover, the Turing pattern is merely one portion of the phase diagram that describes extended patterns and states of the intraresonator field that may be leveraged for laser and frequency-comb generation. Through GVD engineering via waveguide geometry in advanced integrated nonlinear photonics platforms, it is possible to control the phase matching that determines the output frequency of an OPO laser. Photonic-crystal ring resonator (PhCR) devices, which enable manipulation of laser propagation in a medium, offer a powerful control of phase matching for nonlinear optics. PhCR tailoring of the resonator mode structure is enhanced by high finesse. PhCRs can support resonator OPO through both phase matching and resonator finesse control.

Therefore, described herein is a laser platform based on degenerate four wave-mixing OPO in a PhCR. Exemplary embodiments exploit a PhCR structure to control laser propagation without loss at the pump wavelength of the OPO; whereas, the waveguide ring resonator offers a broadband, high finesse mode structure to support the signal and idler modes of the OPO. Exemplary devices may be inscribed with an edgeless nanopattern on the inner wall that opens a photonic bandgap (BG) for the single azimuthal mode that may be excited with a pump laser. By coupling forward and backward propagations of this one azimuthal mode, two modes may be obtained with a frequency shift to higher and lower frequencies compared with the unperturbed mode, respectively. Either the higher or the lower frequency mode directly enables OPO phase matching with respect to a pair of other azimuthal modes to generate signal and idler waves. Hence, the PhCR BG is a single parameter that may be used to provide laser-wavelength access across >100 THz from a single-frequency pump laser. Moreover, the forward and backward couplings associated with the PhCR BG creates bidirectional propagation of the OPO laser. Exemplary embodiments include high conversion efficiency, low additive frequency noise in wavelength conversion, and precision output frequency tuning. These properties are enabled by control of phase matching in the PhCR.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows, according to some embodiments, a schematic and cross-sectional view of a continuous-wave laser source.

FIG. 2 shows, according to some embodiments, a schematic view of a continuous-wave laser source.

FIG. 3 shows, according to some embodiments, a ring resonator and detailed view thereof.

FIG. 4 shows, according to some embodiments, a cross-sectional view of a layer stack of a ring resonator.

FIG. 5 shows, according to some embodiments, a flow diagram of a process of designing a continuous-wave laser source.

FIG. 6 shows, according to some embodiments, a flow diagram of a process of fabricating a continuous-wave laser source.

FIG. 7 shows, according to some embodiments, a flow diagram of a process of fabricating a continuous-wave laser source.

### DETAILED DESCRIPTION

A detailed description of one or more embodiments is presented herein by way of exemplification and not limitation.

It has been discovered that a process for making a laser source provides a continuous-wave laser source with a target output wavelength that can include an optical parametric oscillation (OPO) and a photonic-crystal resonator (PhCR).

Advantageously, the process for making a continuous-wave laser source makes a PhCR that takes an input or pump laser of one wavelength and outputs a laser with the target wavelength. The process for making a continuous-wave laser source involves a photonic-integrated circuit (PIC) that includes a laser waveguide layer, a laser cladding layer, and a substrate. The PIC structure provides a structure for making a frequency-tunable laser source, e.g., by using semiconductor processing techniques. Beneficially, exemplary processes for making a continuous-wave laser source provide the continuous-wave laser source that has superior noise characteristics, tunability of the target output wavelength, and optical amplification of a secondary laser at the target output wavelength.

Frequency-matching of resonator modes naturally dictates the OPO output frequencies, and GVD and Kerr frequency shifts are the principal contributions. OPO frequency matching may be quantified with the integrated dispersion,

Dᵢₙₜ(μ)=ν_{μ}−(ν₀+FSR·μ), (1)

Where ν_{μ} are the cold-cavity resonator mode frequencies, p is the mode number relative to the pump laser (μ=0), and FSR is the free-spectral range. The Kerr frequency shift is not accounted for here and is twice as large for μ=0 than the pump mode. The balance of the power-dependent parametric gain and Kerr shift enable OPO in the anomalous GVD regime, which is specialized for OPO frequency matching since Dᵢₙₜ is positive near the pump; whereas, normal GVD does not assist in frequency matching as the directionality of the Kerr shift inhibits phase matching. The purpose of PhCR is to open a BG that uniquely phase matches OPO under a variety of GVDs, providing a mechanism to design lasers for wavelength access. For example, the engineered BG of an otherwise normal GVD PhCR directly phase matches OPO, which is not possible in ordinary ring resonators. PhCRs substantially modify the resonator mode measured by frequency shifts (GHz) compared to the linewidth (hundreds of megahertz) and the effect on nonlinear optics, although the ring structure primarily guides light in the device.

Degenerate four-wave-mixing based OPO conserves energy and requires phase matching to support appreciable parametric gain. Resonator modes with perfect phase and frequency matching in terms of Dᵢₙₜ satisfy the equation,

Dᵢₙₜ(μ)=−Dᵢₙₜ(−μ). (2)

Practical device design seeks to minimize frequency mismatch of modes symmetric about the pump to less than a ring resonator linewidth (δ), Dᵢₙₜ(μ)+Dᵢₙₜ(−μ)<δ. The quantity Dᵢₙₜ is zero by construction at the pump mode (μ=0), and Dᵢₙₜ(μ=0)<0, which cannot satisfy Eq. (2). However, an analogous PhCR opens a BG on a single ring resonator mode for the pump laser. Then, by pumping the red shifted (i.e., shifted to lower frequency) PhCR BG-shifted mode (μ=0), OPO is phase matched at two modes symmetric about the pump, since the pump mode is frequency shifted in a fashion consistent with the GVD of the PhCR. The spacing of the generated OPO frequencies is δv_{OPO}=vₛ−vᵢ, where vₛ and vᵢ are the generated OPO signal and idler frequencies.

In practice, higher-order dispersion can be a significant consideration, creating the more complex Dᵢₙₜ trends of a realistic PhCR device. In practice, the GVD may be tuned using the geometry of the ring resonator. For example, the Dᵢₙₜ are calculated for experimental ring resonator geometries using tantala (Ta₂O5) waveguides with a thickness of 570 nm, top and side air cladding, a SiO₂ bottom cladding, and a ring radius (RR) of 22.5 μm, measures to the center of the ring waveguide. Different GVDs may be achieved by changing the ring waveguide widths (RWs), which may be, for example, 1625 nm and 1710 nm.

To summarize, a BG can be used with arbitrary GVD profiles to enable OPO across a widely tunable spectral range. This contrasts typical GVD constraints for ordinary ring resonator OPO phase matching, which includes the anomalous GVD regime which enables near-pump OPO but results in cascaded four-wave-mixing at higher optical power and the near-zero GVD regime, which enables potentially wide-span OPO but requires careful GVD tuning to access the narrow spectral range near the zero-GVD point.

The physical mechanism to open the BG is fabrication of a modulation on the inner wall of the ring resonator. The magnitude of the BG depends on the amplitude of the photonic crystal (APhC), and the optical frequency of the PhC BG depends on the modulation period 2·m, where m is the azimuthal mode order of the ring resonator mode where the BG is open.

With the context of PhCR OPOs presented above, we turn now to fabrication. To create PhCRs, the Ta₂O₅-integrated nonlinear photonics platform may be used. Ta₂O₅ offers advantages for PhCR OPOs, including access to high quality factor in the 1064-nm, 1550-nm, and 2000-nm wavelength bands and precision control of GVD due to <1 nm film thickness variation across a 75-mm wafer. A 570-nm thick Ta₂O₅ film may be deposited on an oxidized silicon wafer by ion-beam sputtering, and designs may be transferred to the Ta₂O₅ layer through electron-beam lithography and fluorine inductively coupled plasma—reactive ion etching. Thermal annealing in air for several hours at 500° C. reduces oxygen vacancies present in the Ta₂O₅ material. Such a fabrication process may yield more than 20 chips with −100 ring resonators per chip in a focused 2-day fabrication period. Lensed fibers may be used to insert and collect light from the bus waveguides, which use inverse tapers of length 200 μm and width 2.75 μm at the edge of the chips to best mode match to the lensed fibers, for example. A straight bus waveguide geometry may be used to couple light to the PhCR, which features a typical intrinsic quality factor of 2×10⁶, consistent across the range of BG measured, demonstrating no appreciable loss in the PhCR.

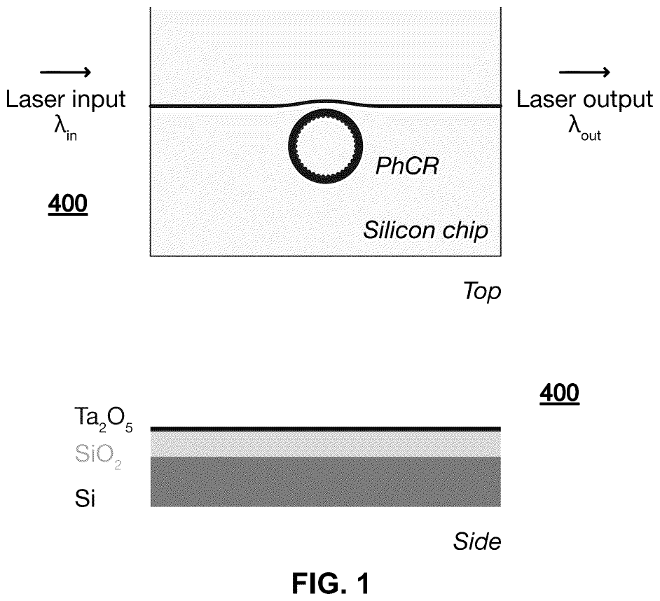

Turning now To FIG. 1, a continuous-wave laser source is shown in top schematic and cross-sectional views. Continuous-wave laser source 400 provides wide and tunable wavelength access, based on integrated nonlinear photonics. Continuous-wave laser source 400 can be used for communication, quantum sensing, and signal generation. Moreover, continuous-wave laser source 400 can be used for nonlinearity in integrated photonics and provides diverse spectral regions, high coherence, and compatibility with semiconductor processing. It should be appreciated that PhCRs are nanophotonic devices integrated on a semiconductor wafer. The nanostructure of a PhCR provides propagation-velocity control of certain light frequencies. Continuous-wave laser source 400 is a tunable-laser that provides customization of output wavelength and fills technical deficiencies of conventional technology and also provides compactness, simplicity, and efficiency.

Continuous-wave laser source 400 includes a photonic-crystal resonator with integrated-photonics and converts a pump laser to a laser of a new wavelength. Continuous-wave laser source 400 is a versatile laser source that can be tailored to produce a wide output wavelength range. Continuous-wave laser source 400 provides unique functionalities such as laser amplification and wavelength transduction. With continuous-wave laser source 400, a single design parameter of the PhCR changes the output wavelength.

Continuous-wave laser source 400 receives an input laser light and produces therefrom output laser light with a tunable wavelength. Continuous-wave laser source 400 includes an optical resonator and photonic crystal for a photonic crystal resonator (PhCR). Properties of the optical resonator and the photonic crystal provide optical parametric oscillation with the input laser and produce a selected output laser light wavelength. When the input laser is tuned at the resonance frequency of the PhCR, the output laser light is automatically generated by nonlinear optical parametric oscillation.

The photonic crystal of continuous-wave laser source 400 controls optical parametric oscillation such that a specific input laser wavelength results in a desired output laser wavelength. Access to laser wavelength can be used in commercial applications, and continuous-wave laser source 400 converts conventional laser sources in developed wavelength bands to bands with novel or commercially challenging applications.

FIG. 1 shows some features of continuous-wave laser source 400, wherein PhCR is formed on an oxidized silicon wafer from a material such as tantalum pentoxide or silicon nitride. Characteristic parameters for optimization for making continuous-wave laser source 400 include thickness of the silicon wafer, the thickness of the SiO2 layer, the thickness of integrated photonics material layer, and the integrated photonics material. Further, continuous-wave laser source 400 includes a ring resonator 110, a grating 114 disposed along the inner edge of the ring, and an integrated waveguide 116 that couples laser power into and out of the PhCR. The amplitude and period of the grating are chosen to facilitate optical parametric oscillation for the input laser wavelength and the desired output laser wavelength in concert with the PhCR device layer thickness and the width of the ring resonator waveguide.

Continuous-wave laser source 400 can include integrated photonics and nonlinear optics to satisfy application requirements. The output wavelength can be varied over a wide range with a high degree of independence from the pump wavelength. Continuous-wave laser source 400 provides high conversion efficiency, low intensity noise, and high spectral coherence. Moreover, Continuous-wave laser source 400 provides functionalities absent in conventional lasers such as parametric amplification and phase-coherent spectral transduction. Continuous-wave laser source 400 is an advance in laser-wavelength access and optical-signal processing.

Continuous-wave laser source 400 is versatile, practically material independent, can be implemented for a wide wavelength range, and independent of particular integrated-photonics device layer properties and geometry. Continuous-wave laser source 400 receives laser light as input and produces a laser with a widely tunable output wavelength. Continuous-wave laser source 400 includes optical parametric oscillation, phase-matched via the optical bandgap of a photonic crystal resonator. Hence, by manipulating the bandgap through the nanofabrication process, continuous-wave laser source 400 has universal phase matching for the optical parametric oscillation and amplification processes that create the tunable-laser output.

Continuous-wave laser source 400 substantially advances the capability for laser-wavelength access. Conventional laser technology predominantly achieves wavelength diversity by customization of laser-gain material, which is complex and expensive to change, and, with integrated photonics, there is scarcity of laser-gain materials. Continuous-wave laser source 400 overcomes these technical limitations of conventional technology and is a versatile tunable laser source that can include integrated photonics and integrated laser platforms to provide laser-wavelength coverage in difficult or impossible to satisfy spectral regions.

Conventional technology also suffers from disadvantages in semiconductor gain media that must be customized to cover new spectral ranges. Such customization is often complex and expensive, and it can be impractical to realize lasers at all. Continuous-wave laser source 400 provides laser-wavelength coverage without onerous customizations like new materials or new laser structures. Continuous-wave laser source 400 provides more straightforward laser-wavelength access than conventional technology.

Continuous-wave laser source 400 produces laser output over a wide range of wavelengths without expensive customization of laser technology. Continuous-wave laser source 400 increases the output wavelength range over commercialized laser technology. Continuous-wave laser source 400 can receive a telecom laser at 1550 nm, for example, and produce an output wavelength over a much broader range. Hence, Continuous-wave laser source 400 can increase the functionality of existing lasers.

The process for making a continuous-wave laser source facilitates design of the PhCR, which is disposed upon a photonic integrated circuit.

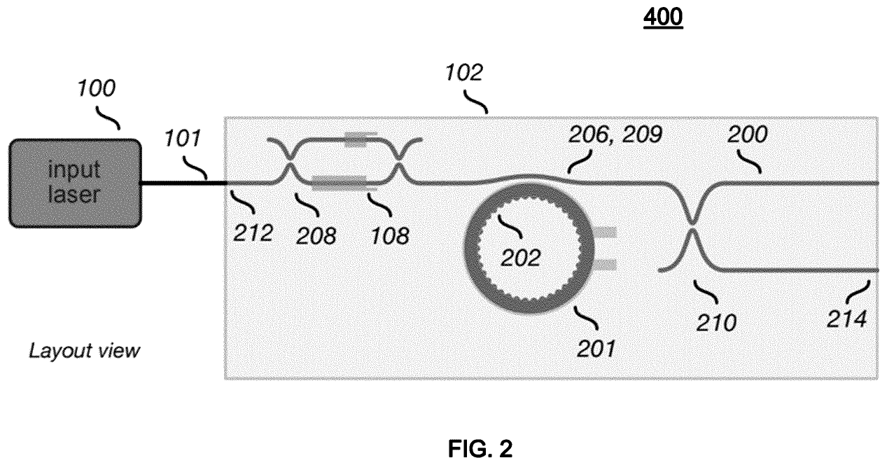

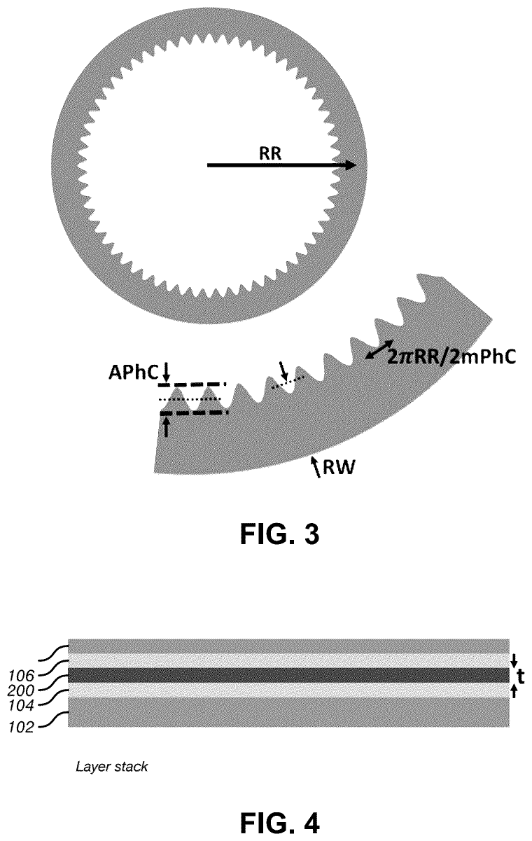

Referring now to FIGS. 2-4, shown is an exemplary embodiment of continuous-wave laser source 400. Elements of the photonic crystal resonator disposed upon the photonic integrated circuit include an input laser 100, optical fiber 101, substrate 102, lower cladding layer 104, upper cladding layer 106, electrical control layer 108, photonic device layer (PDL) 200, elements of the PIC device layer, PhCR 201, amplitude (APhC) and periodicity (mPhC) of the photonic crystal structure 202, width (RW) 240, radius (RR) 250, and thickness (t) 260, of the ring resonator structure. An input laser waveguide coupler 206, input laser intensity modulator 208, output laser waveguide coupler 209, output laser wavelength filter 210, input laser edge coupler (waveguide width WW) 212, and output laser edge coupler 214, may also be included.

In an embodiment, continuous-wave laser source 400 includes an input laser and a photonic crystal resonator disposed upon a photonic integrated circuit. In an embodiment, a process for making a continuous-wave laser source includes: providing suitable materials; designing the photonic crystal resonator for laser generation at the target wavelength; evaluating optimal candidate design results; iterating material selection; designing PhCR process with constraints; forming the PhCR on the PIC; testing and validating the laser source operation at the target wavelength and subordinate laser source properties.

The physics of OPO involves phase matching, i.e., momentum and energy conservation, of the input laser, the output laser of the target output wavelength, and a complementary, second output laser, which is a byproduct of OPO that are all resonant in the PhCR. Momentum conversation of these three lasers (input, output, and complementary) is intrinsic in a resonator. Comparatively, energy conservation of the three lasers balances nonlinear frequency shifts and the group-velocity dispersion property of the PDL. This requirement places restrictions on the output laser wavelength, the PDL material, and the geometry of the resonator, such that only a limited range of target wavelengths can be realized. Continuous-wave laser source 400 with PhCRs for OPO laser sources provides a new mechanism to realize phase matching, accommodating a vast and practically universal range of target output wavelengths and enabling operation in otherwise impractical device geometries.

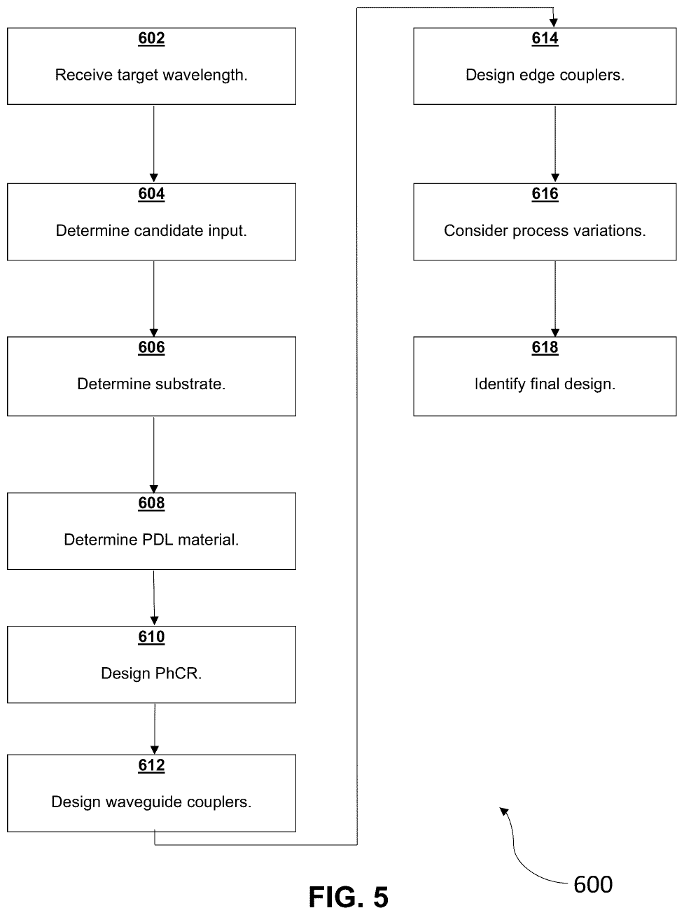

Turning now to FIG. 5, shown is a process 600 for producing an output laser wavelength with continuous-wave laser source 400 and includes, at block 602, receiving a target output wavelength, and subordinate properties of the laser source. Exemplary subordinate properties include output power and linewidth. Other useful subordinate properties include polarization, wavelength tuning range, resolution, and bandwidth.

At block 604, a candidate wavelength of the input laser 100 may be determined. Preferably, an optimal commercially available off-the-shelf candidate input laser 100 is determined, having the candidate wavelength. As used herein, “optimal” refers to the best selection of a particular laser source property without impeding optical parametric oscillation or output laser subordinate properties. Exemplary input laser wavelengths are the 1530-1570 nm range, the 1300 nm range, and the 1064 nm range. Further exemplary laser wavelengths include include 980 nm and 780 nm.

At block 606, an optimal substrate material (102) to accept deposition of the PDL (200) and cladding layers (104 and 106) may be determined. Silicon is a preferred substrate material. Other exemplary substrate materials include fused silica, InP, GaAs and Al₂O₃.

At block 608, an optimal material candidate of the PDL 200 may be determined. Preferably, the material is chosen such that the refractive index is larger than that of the cladding layers; the nonlinear Kerr index is sufficiently large; the transparency spectrum supports low optical loss propagation, i.e., extinction coefficient, at relevant wavelengths; and the PDL is compatible with reactive ion etching. Ta2O5 and Si3N4 are preferred PDL materials. Other exemplary PDL materials include GaAs, silicon oxynitride, AlN, SiO2, and AlGaAs.

At block 610, an optimal design of the PhCR 201 may be determined. Preferably, t of the PDL 200 is calculated to optimize phase-matching, restricted by deposition and fabrication constraints of the PDL. Additionally, RW and RR of the PhCR 201 is calculated to further optimize phase-matching, restricted by fabrication constraints of the PDL 200 and optimal candidate properties of the PhCR 201 as disposed upon the PDL. A preferred range of RR is 10 μm to 200 μm. More preferably, RR falls in the range of 25 μm to 50 μm, depending on required phase-matching. A preferred range of RW is 700 nm and 4000 nm. More preferably, RW falls in the range of 1000 nm to 1700 nm, depending on required phase-matching.

The period of the photonic-crystal modulation, mPhC, may also be calculated for compatibility with the input laser wavelength wavevector, k: mPhC=k*RR.

The amplitude of the photonic-crystal modulation, APhC, may be calculated to provide phase matching. Preferably, the range of APhC is 2 nm and 500 nm. More preferably, APhC falls in the range of 15 nm and 50 nm, depending on required phase-matching.

Therefore, at least one candidate set of PhCR 201 parameters (t, RR, RW, mPhC, APhC) may be determined. If there is not a candidate set of PhCR parameters to satisfy the target output wavelength, then the candidate wavelength of the input laser and or materials chosen above should be revised.

At block 612, an optimal design of the input and output PhCR waveguide couplers 206, 209 may be produced. The geometrical parameters of input PhCR coupler 206 may be calculated so that the external coupling rate at the input laser wavelength and the target output wavelength 209 is consistent with the optimal candidate PDL 200.

As part of this design, the PhCR (201) and input bus waveguide mode profiles may be calculated in order to compute the PhCR coupling rate at the input, output, and complementary wavelengths. The optimal design is determined by the generated coupling rates, which satisfy the required input and output laser subordinate parameters.

At block 614, an optimal design of the input 212 and output 214 edge couplers may be determined. In particular, an optimal set of input and output optical fibers 101 is determined. Exemplary optical fibers have the property of single mode and polarization maintaining at the operation wavelength. Performing optical mode overlap calculations at the interface between the edge couplers 212, 214 and the optical fibers, determine the geometrical size, WW, of the input and output edge coupler to minimize insertion loss, constrained by the optimal properties of the PDL 200.

At block 616, process variations for device feasibility may be considered, optionally performing any of the above steps. The operable dimensional tolerance of the fabrication process may be determined by calculating the sensitivity of the target wavelength to RW and t. Preferably, the sensitivity of RW is +/−25 nm. More preferably, the exemplary sensitivity of t is +/−10 nm. If the sensitivity of the target wavelength to RW and t falls outside the exemplary range, then you may return to the previous steps and generate updated optimal designs.

At block 618, at least one optimal candidate design of the laser source disposed upon the photonic integrated circuit is identified.

Considering the optimal candidate design of the laser source from block 618, further elements may be optionally produced upon the photonic integrated circuit to enhance and enable subordinate properties of the laser source. Exemplary further elements of the PIC include wavelength filters 210 and laser source routing and combinations thereof. Other optional elements include a thermo-optic phase shifter, Mach Zehnder interferometer intensity modulator 208, waveguide splitters, and other passive elements for laser routing and system monitoring.

Optionally, wavelength filtering elements 210 required to route the output laser to output laser edge coupler 214 may now be determined. Transmission of a coupled waveguide section operable for interference of two or more optical modes may be calculated, and a wavelength filtering device according to the output laser subordinate properties may be determined. Exemplary design methods and elements include multimode interference waveguides, coupled waveguide filters, and microresonator filters. Other optional design methods and elements include inverse design and coupled resonator devices.

Optical phase elements to laser control propagation phase may be determined. An exemplary optical phase element is a thermo-optic phase shifter implemented with a resistive heater communicating with a waveguide. Other optional optical phase elements are microresonator phase shifters, electro-optic phase shifters, and phase change materials.

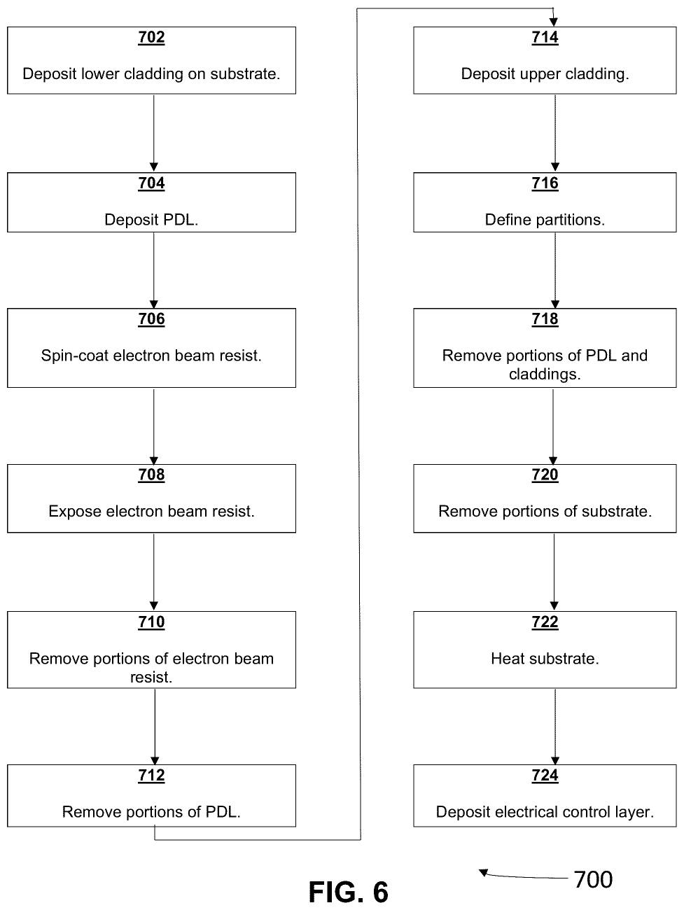

Turning now to FIG. 6, shown is a fabrication process 700 for making an exemplary continuous-wave laser source. In particular, the process makes the photonic crystal resonator and disposes it upon the photonic integrated circuit.

At block 702, a deposition tool is used to deposit the lower cladding layer 104 onto the substrate 102.

At block 704, a deposition tool is used to deposit the photonic device layer upon the substrate 102 and lower cladding 104.

At block 706, a spin coater is used to spin-coat electron-beam resist and a protective-conductive coating.

At block 708, an electron beam lithography tool is used to expose the electron beam resist from a computer file with a plurality of optimal designs for the photonic design layers.

At block 710, an electron-beam resist developer is used to selectively remove portions of the electron beam resist.

At block 712, an inductively coupled plasma reactive ion etcher is used to selectively remove portions of the PDL 200.

At block 714, a deposition tool is used to deposit the upper cladding 106.

At block 716, a laser lithography tool and photoresist operation is used to define partitions of the substrate 102 into sections containing a subset of the optimal designs.

At block 718, an inductively coupled plasma reactive ion etcher is used to remove portions of the upper cladding 106, photonic device layer, and lower cladding 104.

At block 720, an inductively coupled plasma reactive ion etcher is used to remove portions of the substrate 102.

At block 722, a furnace is used to heat the substrate 102 in the presence of a nitrogen and oxygen gas mixture.

At block 724, a metal sputtering tool is optionally used to deposit electrical control layer 108.

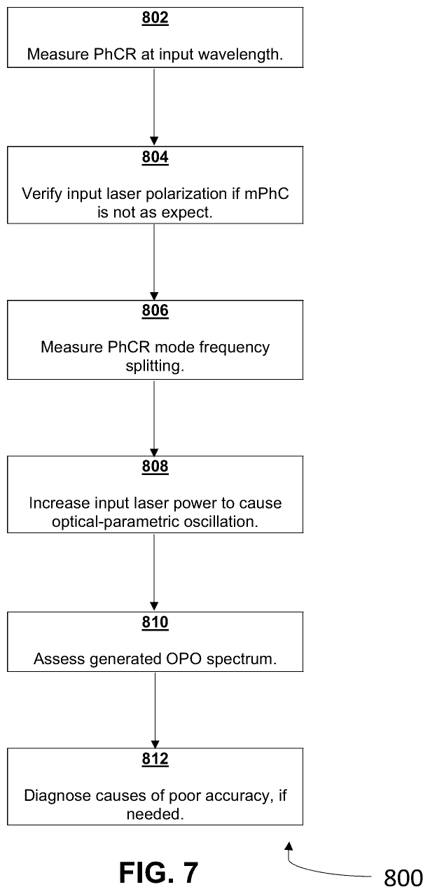

Referring now to FIG. 7, shown is a process for determining operational properties of a continuous-wave laser source 400.

At block 802, the PhCR 201 device is measured at the candidate input wavelength to verify mPhC is within fabrication tolerances. Preferred mPhC agreement is within (mPhC+/−1). The mPhC agreement is determined by fabrication (RR, RW, APhC) and PDL (200) layer deposition (t) tolerances.

At block 804, if the mPhC is outside of the expected range, the input laser polarization should be verified as correct.

At block 806, if the mPhC is correct within fabrication tolerances, the PhCR mode frequency splitting may be measured.

At block 808, pump laser power applied to the target photonic crystal mode is increased until OPO generation occurs, and the output spectrum and other subordinate properties of the laser source are measured.

At block 810 the generated OPO spectrum and other output laser subordinate properties are compared with designed phase-matched wavelengths to determine accuracy in comparison with fabrication tolerances.

At block 812, poor accuracy in output laser wavelength compared with design phase-matched wavelengths may indicate problems with fabrication due to inaccurate geometry (incorrect t, RW, RR compared with target values). In this case, measurement and comparison of PhCR free-spectral range is recommended. Incomplete etch of PDL (200) may also be a cause, and scanning electron microscope imaging is recommended to verify complete PDL etch. Another cause may be inaccurate knowledge of PDL (200) or cladding refractive indices (104, 106). Ellipsometry of PDL and cladding layers is recommended to diagnose this issue.

Continuous-wave laser source 400 can be made of various elements and components and can have sizes. Elements of continuous-wave laser source 400 can be made of a material that is physically or chemically resilient in an environment in which continuous-wave laser source 400 is disposed. The elements of continuous-wave laser source 400 can be monolithic in a single physical body or can be separate members that are physically joined.

Continuous-wave laser source 400 can be made in various ways. It should be appreciated that continuous-wave laser source 400 includes a number of optical, electrical, or mechanical components, wherein such components can be interconnected and placed in communication (e.g., optical communication, electrical communication, mechanical communication, and the like) by physical, chemical, optical, or free-space interconnects. The components can be disposed on mounts that can be disposed on a bulkhead for alignment or physical compartmentalization. As a result, continuous-wave laser source 400 can be disposed in a terrestrial environment or space environment.

Processes and devices described herein have further discussion and characterization provided in Jennifer A. Black, Grant Brodnik, Haixin Liu, Su-Peng Yu, David R. Carlson, Jizhao Zang, Travis C. Briles, and Scott B. Papp, “Optical-parametric oscillation in photonic-crystal ring resonators,” Optica 9, 1183-1189 (2022), which is hereby incorporated herein by reference in its entirety.

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix (s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

What is claimed is:

1. A method of designing a continuous-wave laser source having a target output wavelength and an input laser with a wavelength different from the target output wavelength, the method includes the steps of:
receiving the target output wavelength, and subordinate properties of the laser source;
determining a candidate wavelength of the input laser and materials of the substrate, lower cladding, photonic device layer (PDL), and upper cladding;
producing an optimal design of a photonic crystal resonator (PhCR) enabling optical parametric oscillation (OPO); and
producing an optimal design of the input and output PhCR waveguide couplers;
wherein, the OPO is phase-matched, thereby conserving momentum and energy of the input laser and output laser wavelength, and
wherein a bandgap of the PhCR is varied to provide said phase-matching.

2. The method of claim 1, wherein subordinate properties of the laser source include output power and linewidth.

3. The method of claim 2, wherein subordinate properties of the laser source include polarization, wavelength tuning range, resolution, and bandwidth.

4. The method of claim 1, wherein the step of determining includes calculating thickness of the PDL to optimize phase-matching, restricted by deposition and fabrication constraints of the PDL.

5. The method of claim 1, wherein the step of producing an optimal design of the PhCR includes calculating ring width and ring radius of the PhCR to optimize phase-matching, restricted by fabrication constraints of the PDL and optimal candidate properties of the PhCR as disposed upon the PDL.

6. The method of claim 5, wherein the ring radius is between 25 μm to 50 μm.

7. The method of claim 5, wherein the ring width is between 1000 nm and 1700 nm.

8. The method of claim 1, wherein the PDL comprises one of Ta2O5, a metal-oxide mixture of TiO2:Ta2O5, or Si3N4.

9. The method of claim 1, wherein the PDL comprises one of GaAs, silicon oxynitride, AlN, SiO2, or AlGaAs.

10. The method of claim 1, wherein the PDL comprises a heterogeneous combination of Ta2O5 or a metal-oxide mixture of TiO2:Ta2O5 and a phase-change material.

11. The method of claim 1, wherein the step of producing an optimal design of the PhCR includes identifying at least one candidate set of PhCR parameters including thickness, ring radius, ring width, amplitude and periodicity of the PhCR.

12. The method of claim 1, wherein the step of producing an optimal design of the input and output PhCR waveguide couplers includes calculating geometrical parameters of an input PhCR coupler so that an external coupling rate at the wavelength of the input laser and the target output wavelength is consistent with the PDL.

13. A method of fabricating a photonic crystal resonator for use in continuous-wave laser source having a target output wavelength and an input laser with a wavelength different from the target output wavelength, the method includes the steps of:
depositing a lower cladding layer onto a substrate;
depositing a photonic device layer upon the substrate and lower cladding;
spin-coating an electron-beam resist and a protective-conductive coating;
exposing the electron beam resist using electron beam lithography;
selectively removing portions of the electron beam resist;
selectively removing portions of a photonic device layer;
depositing upper cladding;
heating the substrate in the presence of a nitrogen and oxygen mixture;
depositing an electrical control layer,
wherein the steps of exposing the electron beam resist, selectively removing portions of the electron beam resist, and selectively removing portions of a photonic device layer produce a Kerr ring shape having a ring width, a ring radius, an amplitude of a periodic pattern arranged on an inner wall of the ring, and a periodicity of the pattern, and wherein the photonic device layer has a thickness t.

14. The method of claim 13, wherein the ring radius is between 25 μm to 50 μm.

15. The method of claim 13, wherein the ring width is between 1000 nm and 1700 nm.

16. The method of claim 13, further comprising the steps of:
defining partitions of the substrate into sections containing a subset of the optimal designs using a laser lithography tool and photoresist;
removing portions of the upper cladding, photonic device layer, and lower cladding using an inductively coupled plasma reactive ion etcher.
